(19) United States
(12) Patent Application Publication
(10) Pub. No.: US 2022/0392827 A1
(43) Pub. Date: Dec. 8, 2022

(54) HEAT DISSIPATION STRUCTURE AND HEAT DISSIPATION SYSTEM

(71) Applicant: SOUTH UNIVERSITY OF SCIENCE AND TECHNOLOGY OF CHINA, Shenzhen, Guangdong (CN)

(72) Inventors: Xiaodong Xiang, Shenzhen (CN); Tai Quan, Shenzhen (CN); Mei Shen, Shenzhen (CN); Yuejin Guo, Shenzhen (CN); Guobiao Zhang, Shenzhen (GD); Fengwei An, Shenzhen (CN)

(73) Assignee: Southern University of Science and Technology, Shenzhen (CN)

(21) Appl. No.: 17/775,757

(22) PCT Filed: Jun. 10, 2020
(86) PCT No.: PCT/CN2020/095375

§ 371 Date: May 10, 2022

(30) Foreign Application Priority Data
Sep. 10, 2019 (CN) 201910853481.3

(51) Int. Cl. H01L 23/427

(52) U.S. Cl. CPC H01L 23/427

(57) ABSTRACT

Provided are a heat dissipation structure and a heat dissipation system. The heat dissipation structure includes a heat dissipation channel and a plurality of heat dissipation fins. The plurality of heat dissipation fins are arranged on at least one side of the heat dissipation channel. Heat dissipation fins arranged on the same side of the heat dissipation channel are arranged along an extension direction of the heat dissipation channel. The heat dissipation channel and the plurality of heat dissipation fins are each formed as a cavity structure. Each heat dissipation fin includes a first end and a second end arranged opposite to each other. The first end is a closed end, and the second end is an open end. The second end communicates with the heat dissipation channel.

### CROSS-REFERENCE TO RELATED APPLICATIONS

This is a National Stage Application filed under 35 U. S.C. 371 based on International Patent Application No. PCT/CN2020/095375, filed on Jun. 10, 2020, which claims priority to Chinese Patent Application No. 201910853481.3 filed with the China National Intellectual Property Administration (CNIPA) on Sep. 10, 2019, the contents of which are incorporated herein by reference in their entireties.

### TECHNICAL FIELD

The present application relates to the technical field of heat dissipation of semiconductor devices and chips, for example, a heat dissipation structure and a heat dissipation system.

### BACKGROUND

With the development of semiconductor technology, the third-generation semiconductor materials and devices gradually become the “core” supporting the new generation of information technology, energy conservation and emission reduction, and intelligent manufacturing. However, the characteristics of small area and high power of the third-generation semiconductor materials and devices cause the problems of more heating and difficult heat dissipation. Therefore, high power density limits the development and application of third-generation semiconductor devices and chips. Exemplarily, when a gallium nitride (GaN) half-bridge circuit operates at the frequency of 10 MHz and the voltage of 400 V, the heating power density (that is, Joule heat per unit area) of the GaN half-bridge circuit can reach 6,400 W/cm², close to the heat density of the solar surface. Some graphics processing units (GPUs) have the heating power of nearly 300 W in the size of 815 mm², and the heating power density of some GPUs reaches 37 W/cm². The maximum heating power consumption of a central processing unit (CPU) on a chip with the size of 600 mm² reaches 165 W and the heating power density of the CPU reaches 27.5 W/cm². It is predicted that the average power density of high power density devices and chips will reach 500 W/cm², and the local power density in a heat-concentrated area can exceed 1,000 W/cm², far exceeding the currently widely used upper limit (1.5 W/cm²) of the heat dissipation power density of gas convection and the currently widely used upper limit (120 W/cm²) of the heat dissipation power density of liquid convection.

The highest heat resistant junction temperature of the third-generation semiconductor devices and chips is about 90° C. and can reach about 105° C. in special cases. If there is no efficient heat dissipation system, the operating ambient temperature of the devices and chips can exceed the highest heat resistant junction temperature of the devices and chips, that is, the devices and chips operate in an unstable state, resulting in thermal runaway damage.

### SUMMARY

The present application provides a heat dissipation structure and a heat dissipation system to improve the heat dissipation efficiency and avoid thermal runaway damage to devices and chips.

An embodiment of the present application provides a heat dissipation structure. The heat dissipation structure includes a heat dissipation channel and a plurality of heat dissipation fins.

The plurality of heat dissipation fins are arranged on at least one side of the heat dissipation channel. Heat dissipation fins arranged on the same side of the heat dissipation channel are arranged along an extension direction of the heat dissipation channel.

The heat dissipation channel and the plurality of heat dissipation fins are each formed as a cavity structure. Each of the plurality of heat dissipation fins includes a first end and a second end arranged opposite to each other. The first end is a closed end, and the second end is an open end. The second end communicates with the heat dissipation channel.

An embodiment of the present application provides a heat dissipation system. The heat dissipation system includes any heat dissipation structure provided by the preceding embodiment.

The heat dissipation system further includes a heat conduction cavity, a transmission channel and a heat exchange medium. The heat conduction cavity communicates with the heat dissipation structure through the transmission channel. The connection end where the transmission channel is connected to the heat dissipation structure is higher than the connection end where the transmission channel is connected to the heat conduction cavity.

The heat exchange medium in the liquid state is stored in the heat conduction cavity. The transmission channel is configured to transmit the heat exchange medium heated and vaporized in the heat conduction cavity to the heat dissipation structure and return the heat exchange medium condensed and liquefied due to a heat exchange at the heat dissipation structure into the heat conduction cavity.

### BRIEF DESCRIPTION OF DRAWINGS

FIG. 1 is a structural diagram of a heat dissipation system according to one embodiment;

FIG. 2 is a structural diagram of a heat dissipation structure according to an embodiment of the present application;

FIG. 3 is a structural diagram of another heat dissipation structure according to an embodiment of the present application;

FIG. 4 is a structural diagram of another heat dissipation structure according to an embodiment of the present application;

FIG. 5 is a structural diagram of a heat dissipation system according to an embodiment of the present application;

FIG. 6 is a structural diagram of another heat dissipation system according to an embodiment of the present application;

FIG. 7 is a structural diagram of another heat dissipation system according to an embodiment of the present application;

FIG. 8 is a front view of a heat conduction base and a sample to be heat-dissipated according to an embodiment of the present application;

FIG. 9 is a top view of a heat conduction base and a sample to be heat-dissipated according to an embodiment of the present application; and

FIG. 10 is a structural diagram of another heat dissipation system according to an embodiment of the present application.

### DETAILED DESCRIPTION

The present application is described below in conjunction with drawings and embodiments. For ease of description, only part, not all, of structures related to the present application are illustrated in the drawings.

### Embodiment

With the development of semiconductor technology, in view of the characteristics of small area and high power density of third-generation semiconductor materials and devices, the heat dissipation efficiency of a heat dissipation system urgently needs to be improved to avoid the thermal runaway loss of semiconductor devices.

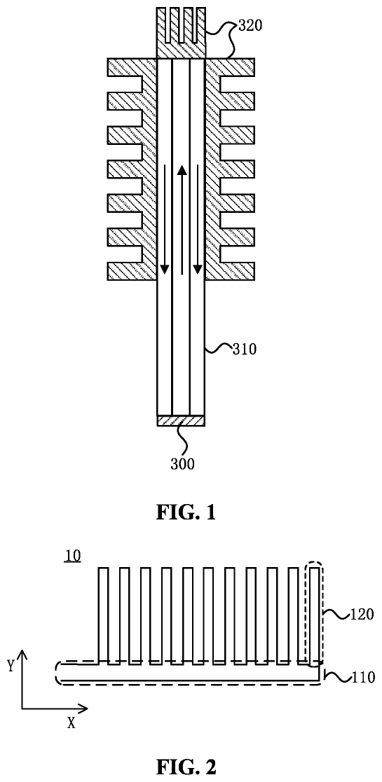

Heat ultimately needs to be exchanged with the atmosphere to complete a complete heat exchange process. Referring to FIG. 1, in the chip heat dissipation scheme, the heat of a chip 300 is conducted to the bottom of a solid heat sink 320 through a heat exchange medium in a connection channel 310. The heat is then exchanged with the external convection medium through the solid heat sink 320 with a centimeter-level path length. However, a solid material whose equivalent heat exchange coefficient on a heat exchange path with a centimeter-level length can match the heat exchange coefficient of a heat exchange medium (such as a phase change material) has not been found. Based on this, for the design of the solid heat sink 320, the solid heat exchange path needs to be shortened and the equivalent heat exchange coefficient needs to be matched with the heat dissipation power density of the phase change heat exchange material. In the final stage of heat exchange with the atmosphere, the most cost-saving way is the natural convection of the atmosphere. The heat dissipation power density of the natural convection of the atmosphere is 0.012-0.15 W/cm² which is far lower than the to-be-achieved heating power density (500-1,000 W/cm²) of the chip. To complete the complete heat exchange process, it is necessary to enlarge the contact area between the heat dissipation surface and the atmosphere by 3 to 6 orders of magnitude, convert the power density mismatch into power matching and achieve the heat exchange matching of the system.

In a heat dissipation structure and a heat dissipation system provided by the embodiments of the present application, a heat dissipation channel and heat dissipation fins are each formed as a cavity structure so that the heat dissipation area of the heat dissipation structure with a small volume can be enlarged by 3 to 6 orders of magnitude, thereby increasing the heat dissipation area. That is, the area compensation is used for achieving the matching between the heating power and the heat dissipation power and improving the heat dissipation efficiency.

Technical schemes in the embodiments of the present application will be described in conjunction with drawings in the embodiments of the present application.

Referring to FIG. 2, a heat dissipation structure 10 includes a heat dissipation channel 110 and heat dissipation fins 120. The heat dissipation fins 120 are arranged on at least one side of the heat dissipation channel 110. The heat dissipation fins 120 arranged on the same side of the heat dissipation channel 110 are arranged along the extension direction of the heat dissipation channel 110. The heat dissipation channel 110 and the heat dissipation fins 120 are each formed as a cavity structure. The heat dissipation fin 120 includes a first end and a second end arranged opposite to each other. The first end is a closed end, and the second end is an open end. The second end communicates with the heat dissipation channel 110.

In the heat dissipation structure provided by the embodiment of the present application, the heat dissipation channel and the heat dissipation fins are each formed as a cavity structure, and the heat exchange can be achieved by using all surface walls of the cavity structure, thereby increasing the heat dissipation area. That is, the heat dissipation area can be increased on a heat dissipation structure with a smaller volume, thereby improving the heat dissipation efficiency and being beneficial to avoiding the thermal runaway damage of devices and chips.

In one embodiment, the cavity structure of the heat dissipation channel 110 and the heat dissipation fins 120 can allow circulation of a heat exchange medium, thereby achieving a heat exchange process.

In one embodiment, the first end of the heat dissipation fin 120 is an end of the heat dissipation fin 120 facing away from the heat dissipation channel 110. Exemplarily, taking the orientation shown in FIG. 2 as an example, the first end of the heat dissipation fin 120 is the top end of the heat dissipation fin 120, the second end of the heat dissipation fin 120 is the bottom end of the heat dissipation fin 120, and the second end is provided with an opening for communicating with the heat dissipation channel 110 to achieve the circulation of the heat exchange medium in the heat dissipation structure 10.

In one embodiment, the heat dissipation channel 110 and the heat dissipation fins 120 are each formed as a cavity structure so that the contact area between the heat exchange medium and the heat dissipation structure 10 and the contact area between the heat dissipation exchange structure and the atmosphere can be increased, thereby increasing the heat dissipation area and being beneficial to improve the heat dissipation efficiency.

Exemplarily, the heat dissipation structure 10 may be referred to as a “three-dimensional (3D) hollow heat dissipation fin group”. The heat dissipation surface area of the sample to be heat-dissipated (for example, a semiconductor device and chip) is in the order of square centimeters (cm²). For the heat dissipation structure 10, the heat dissipation area can be enlarged by 3 to 6 orders of magnitude in a smaller volume. That is, the heat dissipation area can reach orders of 1 square meter (m²) to 10 square meters (m²).

In one embodiment, FIG. 2 only exemplarily shows 11 heat dissipation fins 120 located on the same side of the heat dissipation channel 110. In other implementations, the heat dissipation fins 120 may be located on at least two sides of the heat dissipation channel 110, and the number and form of the heat dissipation fins 120 may be set according to the actual requirements of the heat dissipation structure 10, which is not limited by the embodiments of the present application.

In addition, FIG. 2 only exemplarily shows that the heat dissipation channel 110 extends along the horizontal direction, and the extension direction of the heat dissipation fins 120 is perpendicular to the extension direction of the heat dissipation channel 110, that is, the heat dissipation fins 120 extend along the vertical direction. However, this does not constitute a limitation on the heat dissipation structure 10 provided by the embodiments of the present application. In other implementations, the extension direction of the heat dissipation fins 120 and the extension direction of the heat dissipation channel 110 may be set according to the actual requirements of the heat dissipation structure 10 in conjunction with the spatial position relationship and the sizes of the samples to be heat-dissipated, which is not limited by the embodiments of the present application. The form of the heat dissipation structure 10 will be exemplarily described below in conjunction with FIGS. 2 to 4.

In an embodiment, referring to any one of FIGS. 2 to 4, the heat dissipation channel 110 extends along a first direction X, the heat dissipation fins 120 are arranged along the first direction X, the heat dissipation fins 120 extend along a second direction Y, and the first direction X intersects the second direction Y Moreover, the distance between the first end of a heat dissipation fin 120 and the horizontal plane is greater than or equal to the distance between the second end of the same heat dissipation fin 120 and the horizontal plane.

In this manner, the heat exchange medium in the heat dissipation channel 110 may be dispersed into multiple heat dissipation fins 120. At the same time, the heat exchange medium in the heat dissipation fins 120 may converge into the heat dissipation channel 110. This will be described below in connection with other components of the heat dissipation system.

Exemplarily, when the heat exchange medium is a liquid-vapor phase change material, the gaseous phase change material carrying heat may be dispersed into the plurality of heat dissipation fins 120 through the heat dissipation channel 110. Then, the heat carried by the gaseous phase change material in the heat dissipation fins 120 is finally exchanged with the atmosphere through the inner and outer walls of the heat dissipation fins 120. The heat exchange lowers the temperature of the gaseous phase change material and can condense and recover the liquid phase change material. The distance between the first end of a heat dissipation fin 120 and the horizontal plane is set to be greater than or equal to the distance between the second end of the same heat dissipation fin 120 and the horizontal plane so that the open end of the heat dissipation fin 120 is lower than or equal to the closed end of the heat dissipation fin 120. That is, the open end is horizontal or downward. Thus, the liquid phase change material can flow back from the heat dissipation fins 120 into the heat dissipation channel 110, thereby achieving the circulation of the heat exchange medium.

In one embodiment, FIGS. 2 to 4 only exemplarily show that the heat dissipation channel 110 includes two ends, and one end of the heat dissipation channel 110 is open and the other end of the heat dissipation channel 110 is closed. However, this does not constitute a limitation on the heat dissipation structure 10 provided by the embodiments of the present application. In other implementations, the heat dissipation channel 110 may include multiple ends. At least one of the ends may be configured as an open end, or multiple ends may be configured as open ends. This may be set according to actual requirements of the heat dissipation structure 10, which is not limited by the embodiments of the present application.

Optional directions of the first direction X and the second direction Y are exemplarily described below in combination with actual spatial orientations.

In an embodiment, referring to FIG. 2, the first direction X is the horizontal direction, and the second direction Y is the vertical direction.

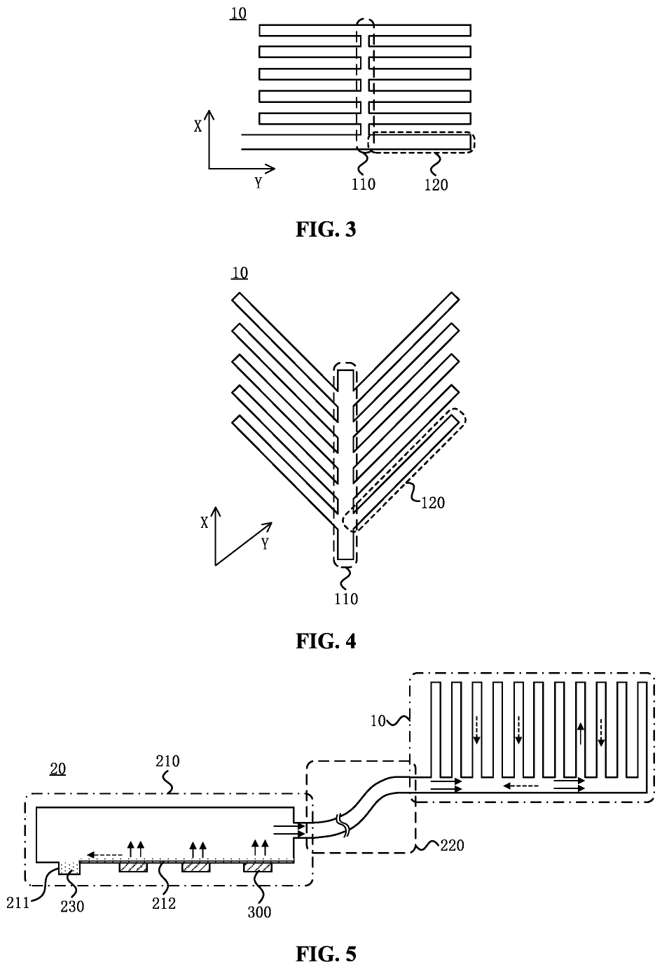

Alternatively, referring to FIG. 3 or FIG. 4, the first direction X is the vertical direction, and the included angle between the second direction Y and the first direction X may be 90° or 45°, that is, the second direction Y may be the horizontal direction or an oblique direction of any angle.

In other implementations, the included angle between the extension direction of the heat dissipation fins 120 and the horizontal direction may be any angle from 0° to 180°, including 0° and 180°, to ensure that the heat dissipation fins 120 are arranged in such a manner that the open ends are horizontal or downward, that is, as long as the liquid heat exchange medium can flow back to the heat dissipation channel 110.

In one embodiment, FIGS. 2 to 4 only exemplarily show that the heat dissipation fins 120 located on the same side of the heat dissipation channel 110 have the same shape which is cylindrical, and the sidewall between the first end and the second end is smooth. However, this does not constitute a limitation on the heat dissipation structure 10 provided by the embodiments of the present application. In other implementations, the heat dissipation fins 120 may be in the shape of a cone, a truncated cone or other three-dimensional shapes. The heat dissipation fins 120 may have the same shape or different shapes. The sidewall of the heat dissipation fin 120 may be formed in a zigzag shape, a folded line shape, an arc shape or any other shapes to ensure that the entire heat dissipation structure 10 has a large heat dissipation area in the premise of a small volume, which is not limited by the embodiments of the present application.

On the basis of the preceding implementations, the embodiments of the present application further provide a heat dissipation system. The heat dissipation system includes any heat dissipation structure provided by the preceding implementations. Therefore, the heat dissipation system has the technical effects of the heat dissipation structure in the preceding implementations. The same content may be understood by referring to the preceding description of the heat dissipation structure and will not be repeated below.

Exemplarily, referring to any one of FIGS. 5 to 7, the heat dissipation system 20 includes the heat dissipation structure 10 and further includes a heat conduction cavity 210, a transmission channel 220 and a heat exchange medium 230. The heat conduction cavity 210 communicates with the heat dissipation structure 10 through the transmission channel 220 and the connection end where the transmission channel 220 is connected to the heat dissipation structure 10 is higher than the connection end where the transmission channel 220 is connected to the heat conduction cavity 210. The heat exchange medium 230 in the liquid state is stored in the heat conduction cavity 210. The transmission channel 220 is configured to transmit the heat exchange medium 230 heated and vaporized in the heat conduction cavity 210 to the heat dissipation structure 10 and return the heat exchange medium 230 condensed and liquefied due to a heat exchange at the heat dissipation structure 10 into the heat conduction cavity 210.

In one embodiment, samples 300 to be heat-dissipated are attached to at least part of the sidewall of the heat conduction cavity 210 (taking that samples 300 to be heat-dissipated are attached to the bottom of the heat conduction cavity 210 in FIGS. 5 to 7 as an example), and the heat of the samples 300 to be heat-dissipated is transmitted to the heat exchange medium 230 through the bottom of the heat conduction cavity 210. The heat exchange medium 230 may be a liquid-vapor phase change medium. Thus, the heat exchange medium 230 is heated and vaporized. In conjunction with FIG. 2 and FIG. 5, the gaseous heat exchange medium 230 is transmitted to the heat dissipation structure 10 through the transmission channel 220 and dispersed by the heat dissipation channel 110 of the heat dissipation structure 10 to the plurality of heat dissipation fins 120. The heat carried by the gaseous heat exchange medium 230 exchanges heat with the atmosphere through the inner and outer walls of the heat dissipation structure 10. Then the temperature of the gaseous heat exchange medium 230 decreases and the gaseous heat exchange medium 230 is condensed and recovered to the heat exchange medium 230 in the liquid state. The heat exchange medium 230 in the liquid state is collected by the plurality of heat dissipation fins 120 into the heat dissipation channel 110 and flows back into the heat conduction cavity 210 through the transmission channel 220.

Exemplarily, in FIGS. 5 to 7, solid arrows represent the transmission path of the vaporized gaseous heat exchange medium 230, and broken arrows represent the transmission path of the liquefied liquid heat exchange medium 230. In FIGS. 5 to 7, only some arrows are exemplarily drawn. The transmission path of the heat exchange medium 230 in other similar structures can be understood with reference to this and is not shown herein.

Exemplarily, in the actual product structure, the sample 300 to be heat-dissipated may be a high-power device or chip. In this case, the sidewall of the heat conduction cavity 210 to which the sample 300 to be heat-dissipated is attached may be configured as a heat conduction base 212 with a high thermal conductivity, to use the heat conduction base 212 to assist heat dissipation. The transmission path of heat may include transmitting the heat generated by the sample 300 to be heat-dissipated to the heat exchange medium 230 through the heat conduction base 212. In the heat dissipation system 20, the transmission path of heat is relatively short, and the heat dissipation efficiency is relatively high.

In one embodiment, in the actual product structure, the sample 300 to be heat-dissipated may include a heat conduction base 212 besides a high-power device and chip. The heating surface of the sample 300 to be heat-dissipated is attached to one side of the heat conduction base 212, and another side of the heat conduction base 212 is attached to the bottom of the heat conduction cavity 210. In this case, the transmission path of heat may include transmitting the heat generated by the sample 300 to be heat-dissipated to the heat exchange medium 230 through the heat conduction base 212 and the bottom of the heat conduction cavity 210 sequentially. In the heat dissipation structure 10, the heat conduction cavity 210 may be integrally formed with the same material, and the preparation process is relatively simple and the cost is relatively low.

The heat conduction cavity 210, the transmission channel 220 and the heat exchange medium 230 are exemplarily described below with reference to FIGS. 5 to 10, separately.

In an embodiment, referring to any of FIGS. 5 to 7, the heat conduction cavity 210 includes the heat conduction base 212 and a storage groove 211. The heat conduction base 212 is disposed as a portion of the bottom surface of the heat conduction cavity 210. The storage groove 211 is disposed on the bottom surface of the heat conduction cavity 210 and located on a side of the heat conduction base 212 facing away from the heat dissipation structure 10. The surface of a side of the heat conduction base 212 facing away from the heat conduction cavity 210 is configured for the sample 300 to be heat-dissipated to be attached to.

In one embodiment, the heat conduction base 212 is configured to change a point heat source into an equivalent plane heat source to increase the effective heat exchange area, thereby reducing the heat conduction power density.

In an embodiment, the thermal conductivity of the heat conduction base 212 is greater than or equal to 500 W/(m·K).

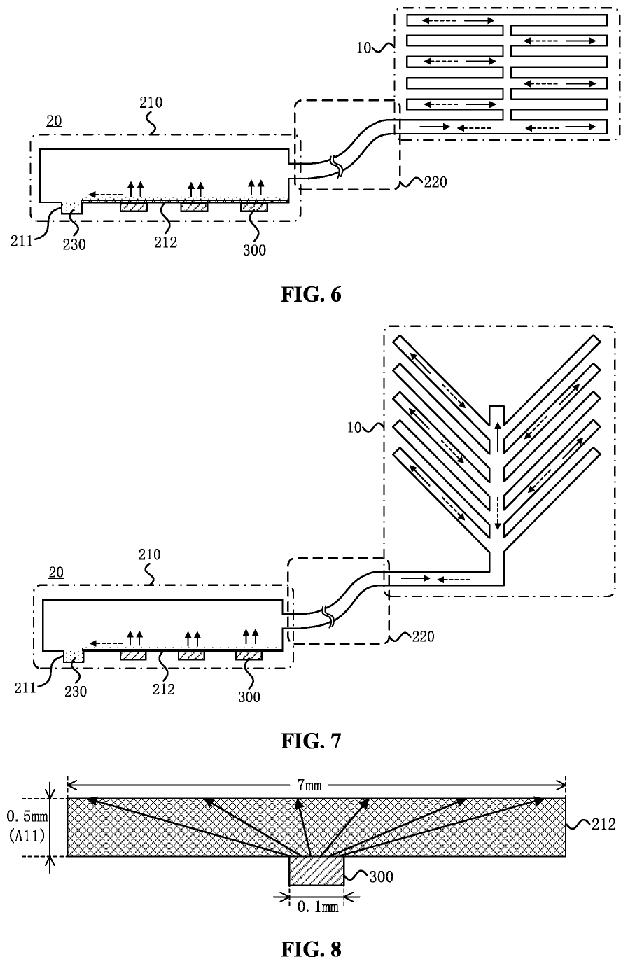

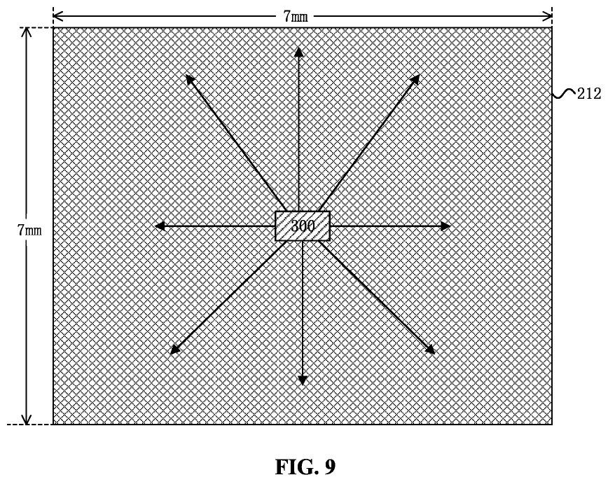

In this manner, by using the heat conduction base 212 with a high thermal conductivity, the heat of the sample 300 to be heat-dissipated can be rapidly diffused along multiple directions of the heat conduction base 212. Referring to FIG. 8 and FIG. 9, directions of arrows in the heat conduction base 212 may represent the diffusion directions of heat from the sample 300 to be heat-dissipated to the heat conduction base 212. In FIG. 8 and FIG. 9, only a few arrows are exemplarily drawn. The diffusion paths of heat also include other paths from the sample 300 to be heat-dissipated to the heat conduction base 212.

In an embodiment, referring to FIG. 8, the material of the heat conduction base 212 includes diamond.

Exemplarily, the thermal conductivity of common materials is shown in Table 1.

TABLE 1
Thermal conductivity table of common materials

| | Thermal Conductivity |
|---|---|
| Material | (W/(m · K)) |
| Aluminum oxide (Al₂O₃) | 30 |
| Silicon carbide (SiC) | 450 |
| Gallium nitride (GaN) | 110 |
| Diamond | 2300 |
| Copper | 401 |
| Aluminum | 237 |

In this embodiment, by using diamond or other ultra-high solid heat conduction material as the material of the heat conduction base 212 with a high heat conduction power density, other materials of the heat conduction base 212 with low thermal conductivity can be replaced, thereby improving the thermal conductivity of the heat conduction base 212. The heat inside the sample 300 (for example, a high power density device and chip) to be heat-dissipated can be more easily conducted to the surface of the heat conduction base 212 facing the inside of the heat conduction cavity 210.

On this basis, to achieve matching between the heating power and the heat dissipation power by area compensation, the ratio between the heating area, the heat conduction area and the heat dissipation area may be set.

Exemplarily, referring to FIG. 9, the ratio A00 of the area of the heat conduction base 212 to the area of the heating surface of the sample 300 to be heat-dissipated satisfies 5≤A00≤20,000. Moreover, the ratio A01 of the heat dissipation area of the heat dissipation structure 10 to the area of the heat conduction base 212 satisfies A01>B01. B01 denotes the ratio of the heating power density of the sample 300 to be heat-dissipated to the heat dissipation power density of natural gas convection.

In one embodiment, the heat conduction base 212 is in contact with the heating surface of the sample 300 to be heat-dissipated. By using the material of the large-area solid heat conduction base 212 with an ultra-high thermal conductivity, the area of the heat conduction base 212 is greatly enlarged at the same heating power so that the heat can be rapidly diffused along the plane and side of the heat conduction base 212 shown in FIG. 8 and FIG. 9. That is, the point heat source becomes the plane heat source so that the heating power density of the heat conduction base 212 is greatly reduced, thereby reducing the heat dissipation difficulty of devices and chips.

Exemplarily, the area ratio A00 may be in the order of hundreds to tens of thousands, thereby effectively enlarging the heating surface and reducing the heating power density.

Exemplarily, the width of the sample 300 to be heat-dissipated may be 0.1 mm, and the length of the sample 300 to be heat-dissipated may be 0.2 mm; the length and width of the heat conduction base 212 are each 7 mm; and the area ratio A00=2,450.

In other implementations, 500≤A00≤5,000, 900≤A00≤8,000, 5,000≤A00≤80,000 or other optional value ranges may be set according to the actual heat dissipation requirements of the heat dissipation system 20, which is not limited by the embodiments of the present application.

In one embodiment, FIG. 7 only exemplarily shows that the shape of the heat conduction base 212 and the shape of the sample 300 to be heat-dissipated is each rectangular. In other implementations, the shape of the heat conduction base 212 may be circular, elliptical, triangular, polygonal or other shapes, and the shape of the sample 300 to be heat-dissipated may be circular, elliptical, triangular, polygonal or other shapes, which is not limited by the embodiments of the present application.

In one embodiment, the heat dissipation area of the heat dissipation structure 10 may include the area of the outer wall of a heat dissipation channel and the area of the outer wall of the heat dissipation fins. The heat exchange medium causes a thermal short circuit between the heat conduction base 212 and the heat dissipation structure 10. By setting A01>B01, the heat dissipation rate may be matched with the heating rate by area compensation, thereby achieving a better heat dissipation effect and avoiding thermal runaway damage.

Exemplarily, the average heating power density of high power density devices and chips will reach 500 W/cm², and the local power density of the heat concentration area may exceed 1,000 W/cm². The maximum heat dissipation power density of natural gas convection may be 1.5 W/cm². B01 may be (500/1.5)=333.34 or (1000/1.5)=666.6.

On this basis, by setting the area of the heat dissipation surface in contact with the atmosphere being enlarged by 3 to 6 orders of magnitude, the power density mismatch can be converted into power matching, thereby achieving the heat exchange matching of the system.

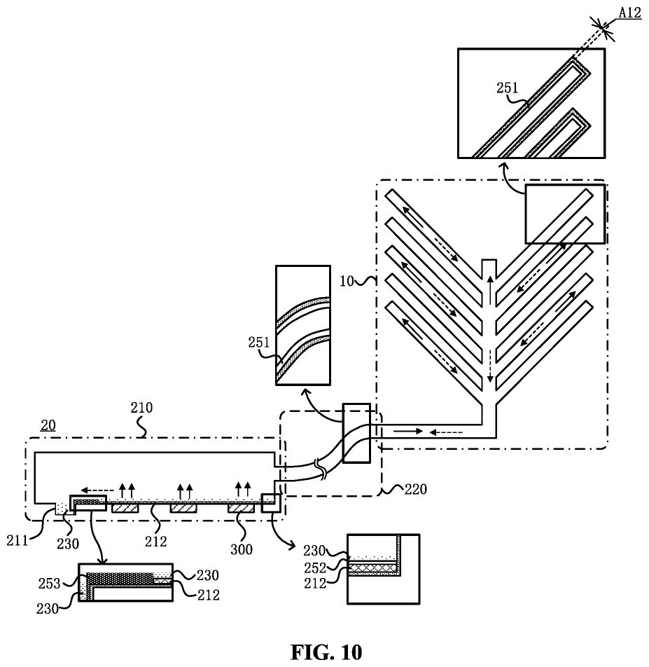

In an embodiment, referring to FIG. 8 and FIG. 10, along the direction from the sample 300 to be heat-dissipated to the heat conduction base 212, the thickness A11 of the heat conduction base 212 satisfies 1 μm≤A11<10 cm. Along the direction from the inside of the heat dissipation structure 10 to the outside of the heat dissipation structure 10, the thickness A12 between the inner wall and the outer wall of the heat dissipation structure 10 satisfies 1 μm≤A12<10 cm.

In this manner, on the one hand, the thickness of the sidewall of the cavity of multiple structures in the heat dissipation system is not too thin, thereby facilitating the overall structural stability of the heat exchange system. On the other hand, the thickness of the sidewall of the cavity is not too thick, thereby ensuring high heat conduction and heat exchange efficiency.

Exemplarily, A11=0.5 mm, and A12=1 mm.

In other implementations, 5 μm≤A11≤5 cm, 8 mm≤A11≤5.8 cm, 5 mm≤A12≤7.5 cm, 8 mm≤A12≤5 cm or other optional ranges may be set, which is not limited by the embodiments of the present application.

In an embodiment, the heat exchange medium 230 may include a heat superconducting phase change material.

In one embodiment, the heat exchange medium 230 is required to connect the heat conduction area of the heat conduction base 212 and the heat dissipation area of the heat dissipation structure 10. The heat exchange medium 230 transmits heat from the heating surface (equivalent to the heat conduction surface of the heat conduction base 212) of the device and the chip to the heat dissipation structure 10. The heat exchange medium 230 is attached to the surface of the heat conduction base 212 of the device and the chip. The heat exchange power density of the heat exchange medium must be of the same order of magnitude as the heating power density of the device and the chip. Moreover, the heat exchange medium 230 must have fast fluidity so that heat can be rapidly transmitted to the heat dissipation structure 10, thereby achieving a thermal short circuit between the heat conduction base 212 and the heat dissipation structure 10.

The gaseous phase heat exchange material has fluidity but insufficient power density. The liquid phase heat exchange material has poor fluidity, and the power density of the liquid phase heat exchange material is not up to the standard. The solid phase material has the power density up to the standard, but does not have fluidity.

In this embodiment, the heat exchange medium 230 is provided as a heat superconducting phase change material which may also be referred to as a “phase change material”, a “liquid-vapor phase change material” or a “liquid phase-vapor phase change heat exchange material” so that the heat exchange medium 230 has the characteristics of power density matching and strong fluidity.

Exemplarily, the heat exchange power density of the liquid phase-vapor phase change heat exchange material may reach 1,000 W/cm².

In other implementations, other types of heat exchange medium 230 may be selected according to the requirements of the heat dissipation system 20 to ensure that the power density of the heat exchange medium 230 is matched with the heating power density, and that the fluidity thereof is good so that the heat conduction base 212 and the heat dissipation structure 10 can be thermally short-circuited. This is not described repeatedly or limited by the embodiments of the present application.

In an embodiment, the transmission channel 220 is a rigid channel or a flexible channel.

In one embodiment, the heat dissipation structure 10 communicates with the heat conduction base 212 of the device and chip through the transmission channel 220. In this manner, it can be achieved that the effective contact area is enlarged. The transmission path of heat includes a gaseous phase change material→ the inner wall of the heat dissipation structure→ the outer wall of the heat dissipation structure→ atmosphere. As such, the contact area may refer to the contact area between the gaseous phase change material and the inner wall of the heat dissipation structure or may refer to the contact area between the outer wall of the heat dissipation structure and the atmosphere.

Exemplarily, when the transmission channel 220 is a rigid channel, the form of the transmission channel 220 is fixed so that the relative position of the heat conduction cavity 210 and the heat dissipation structure 10 is fixed, thereby being beneficial to enhancing the overall structural stability of the heat dissipation system 20.

Exemplarily, when the transmission channel 220 is a flexible channel, the size and form of the transmission channel 220 may be set according to the spatial positional relationship between the heat dissipation structure 10 and the heat conduction cavity 210, such as the distance, the position and the like, and according to requirements such as the arrangement positional relationship of the device and the chip, thereby increasing the design flexibility of the heat dissipation system 20.

In one embodiment, FIGS. 5 to 7 only exemplarily show that one heat conduction cavity 210 communicates with one heat dissipation structure 10 through one transmission channel 220. In other implementations, one heat conduction cavity 210 may be configured to communicate with multiple heat dissipation structures 10 at the same time through multiple transmission channels 220 respectively and may be set according to actual requirements of the heat dissipation system 20, which is not limited by the embodiments of the present application.

In an embodiment, FIG. 10 exemplarily shows a partially enlarged view of the heat dissipation system 20 with the structure in the bold solid line frame. Referring to FIG. 10, the heat dissipation system 20 may further include a hydrophobic film layer 251, a hydrophilic film layer 252 and a water-conducting film layer 253. The hydrophobic film layer 251 covers at least one of the inner wall of the transmission channel 220, the inner wall of the heat dissipation channel 110 or inner walls of the heat dissipation fins 120. The hydrophilic film layer 252 covers at least the surface of the heat conduction base 212 in the heat conduction cavity 210 facing away from the sample 300 to be heat-dissipated. The water-conducting film layer 253 covers at least one of the surface of the groove structure 211 or the inner surface of the heat conduction cavity 210 between the heat conduction base 212 and the groove structure 211.

In one embodiment, the hydrophilic film layer 252 is coated on the heat dissipation surface of the heat conduction base 212, that is, a hydrophilic treatment is performed so that the liquid phase change material can be more easily attached to the surface of the heat conduction base 212 facing the inside of the heat conduction cavity 210. The surface of the heat conduction base 212 is provided with the storage groove 211 in which the heat exchange medium 230 is stored. By performing the water-conducting treatment on the surface of the storage groove 211, the liquid phase change material can conduct to the surface of the heat conduction base 212 of the device and chip more easily. By performing the water-conducting treatment on the inner surface of the heat conduction cavity 210 between the heat conduction base 212 and the groove structure 211, a complete hydrophilic path from the storage groove 211 to the heat conduction base 212 can be formed, thereby enabling the liquid phase change material to transmit from the storage groove 211 to the surface of the heat conduction base 212.

In one embodiment, the hydrophobic treatment is performed on the inner surfaces of the transmission channel 220 and the heat dissipation structure 10 so that the vapor phase change material does not adhere to the inner surfaces of the heat dissipation structure 10 and the transmission channel 220 after condensation, and the vapor phase change material rapidly flows back to the storage groove 211 of the heat conduction cavity 210 along a conducting path and joins the heat exchange cycle again, thereby improving cycle efficiency and further improving heat exchange efficiency.

In an embodiment, the water-conducting film layer 253 includes a fiber structure or a core structure.

In this manner, the water conducting can be achieved through capillary action, and the structure is simple.

In other implementations, other water-conducting film structures may be adopted, as well as any type of hydrophilic film structure and hydrophobic film structure may be adopted, which are not described or limited by the embodiments of the present application.

In one embodiment, in FIGS. 5 to 7 and FIG. 10, multiple samples 300 to be heat-dissipated are attached to the surface of the same heat conduction base 212 facing away from the heat conduction cavity 210. In other implementations, multiple heat conduction bases 212 may be provided. Each of the samples 300 to be heat-dissipated is attached to a respective one of the heat conduction bases 212. In this structure, the water-conducting film layer 253 may cover surfaces of adjacent heat conduction bases 212. Alternatively, other mating relationships may be adopted, which are not limited by the embodiments of the present application.

The heat dissipation process of the heat dissipation system provided by the embodiments of the present application is described below in conjunction with multiple stages of the heat dissipation process of the heat dissipation system.

Exemplarily, the essence of solving the heat dissipation of high power density devices and chips is to solve the problem that the heat dissipation density does not match the heating density in multiple heat dissipation stages. Three stages are taken as an example. In the first stage, heat is conducted from the heating surface of a device or chip to a heat exchange medium through a heat conduction base. In the second stage, the heat exchange medium is in contact with the inner surface of the heat dissipation structure, and the heat is conducted through the inner surface of the heat dissipation structure to the outer surface of the heat dissipation structure. In the third stage, the heat of the outer surface of the heat dissipation structure is exchanged with the convection of the atmosphere, thereby completing a heat exchange cycle.

In the first stage, for solid heat conduction, when the heat transmission path (thickness of the heat conduction base 212) is constant, the equivalent heat dissipation coefficient (h₂) of the next stage needs to be set to be equal to or greater than the equivalent heat dissipation coefficient (h₁) of the heating/heat transmission/heat conduction of the previous stage: h₂≥h₁

In the second stage, for the phase change heat exchange, if the effective contact areas are equal, the phase change heat exchange power density (q₂″) must be equal to or greater than the heating power density (q₁″) of the previous stage: q₂″≥q₁″.

In the third stage, for convection heat exchange, if the effective heat dissipation areas are not equal, the convection heat dissipation power (q₂) needs to be equal to or greater than the power (q₁) of the previous stage: q₂ q₁.

Thus, the embodiments of the present application solve the problem of matching heat exchange power/power density in multiple stages and complete the design of the heat dissipation system 20.

The concepts of power and power density need to be understood. Power is the energy/heat generated or exchanged per unit of time in watts (W). The power density is the power generated or exchanged per unit area in watts per square centimeter (W/cm²).

The operating process of the heat dissipation system 20 is exemplarily described below in conjunction with multiple constituent structures and relative positional relationships of the heat dissipation system 20.

An embodiment of the present application provides a fin-type 3D hollow phase change heat dissipation structure and system. The heat dissipation system 20 includes a heat conduction cavity 210 in which a heat conduction base is located, a heat dissipation structure 10 composed of a fin-type 3D hollow heat dissipation fin and a heat dissipation channel, and a transmission channel 220. A heat superconducting phase change material is stored inside the heat dissipation system 20 as a heat exchange medium 230.

A material with a high thermal conductivity (for example, thermal conductivity≥500 W/(m·K)) such as diamond is used as a heat conduction base 212. The heating surfaces of the high power density devices and chips are attached to the bottom of the heat conduction cavity 210 through the heat conduction base 212.

In one embodiment, the hydrophilic treatment is performed on the heat conduction base 212, and the liquid-vapor phase change material storage groove is located at the bottom of the heat conduction cavity 210. The phase change material can be smoothly and sufficiently coated on the hydrophilic surface through capillary action.

The height of the heat dissipation structure 10 (that is, the fin-type 3D hollow structure) may be higher than the heat conduction base 212. The heat conduction cavity 210 may communicate with the heat dissipation structure 10 through the transmission channel. A flexible transmission channel is provided between the device and chip and the 3D hollow heat dissipation structure to transfer the increased volume of the heat dissipation system to any place and is convenient for the design of the device and the chip. The inner wall of the fin-type 3D hollow structure is coated with a layer of hydrophobic material to reduce the adhesion of the liquid phase change material.

When the heat dissipation system 20 is operating, the device and the chip generate heat with high power density. The heat is transmitted to the phase change material through the heat conduction base 212. With the accumulation of heat, the temperature of the phase change material rises and exceeds the boiling point (phase change temperature). The liquid-vapor phase change heat dissipation material vaporizes and rises, leaving the heat dissipation surface. At the same time, the liquid phase change material is stored in the groove on the side and quickly adsorbed on the heat dissipation surfaces of the device and the chip through the capillary phenomenon and the hydrophilic film, supplementing the vaporized material. The vaporized phase change material passes through the transmission channel (hydrophobic treatment) to the fin-type 3D hollow structure. The vapor phase change material is in contact with the inner surface wall of the 3D hollow heat dissipation fin, and heat is transmitted to the 3D hollow heat dissipation fin through the phase change material. The heat of the phase change material decreases and the temperature drops below the boiling point (phase change temperature). The phase change material changes into a liquid state again. As a result of the hydrophobic treatment performed on the inner wall of the 3D hollow structure and the inclined downward included angle formed between the inner wall of the 3D hollow structure and the horizontal direction, the condensed phase change material passes through the transmission channel and then flows back and adheres to the surface of the heat conduction base or the storage groove of the phase change material. The phase change material is attached to the heat dissipation surface of the heat conduction base again through the capillary phenomenon and the hydrophilic film layer to complete a cycle of the phase change material.

The heat is transmitted from the phase change material to the hollow heat dissipation fin. The heat dissipation fin is hollow inside, the thickness of the surface wall thereof is in an order of 1 mm, and the heat conduction power density thereof is matched with the power density of the phase change material. The heat is transmitted through the inner surface wall of the heat dissipation fin to the outer surface wall of the heat dissipation fin, and the temperature rise of the heat dissipation wall is controlled at about 1° C. The outer surface wall of the 3D hollow heat dissipation fin is in contact with the air (atmosphere) and transmits heat to the atmosphere through heat exchange. Since the heat dissipation area is 3 to 6 orders of magnitude higher than the surface area of the chip, the heating power of the chip matches the heat dissipation power of the atmosphere. The heating heat of the chip is transmitted to the atmosphere to complete a complete heat dissipation cycle.

In the heat dissipation system 20, the phase change medium enables a thermal short circuit to form between the local small-area heat exchange surface with a high heat power density and the non-local large-area heat exchange surface with a low power density. That is, the heating surface and the heat dissipation surface communicate with each other through the phase change medium to form a thermal circuit, thereby improving heat conduction and heat dissipation efficiency. It can also be understood as that a phase change heat exchange material is used as a heat superconducting link to increase the matching area between the hollow heat dissipation fin and the heat dissipation (heat conduction) base of the chip by 4 to 5 orders of magnitude so that the power of the natural gas convection matches the required heat dissipation power.

The heat dissipation system 20 can be applied to heat dissipation of high power density devices and integrated circuit chips of the third-generation semiconductors such as SiC or GaN, solving the heat dissipation problem that the heating power of high power density devices and integrated circuit chips does not match the heat dissipation power thereof and has the advantage of low cost.

Exemplarily, for high power density devices and chips with a heating power density of 500 to 1,000 W/cm², the temperature rise is ≤33° C. That is, in the case where the ambient temperature is 27° C., the chip temperature is ≤60° C., much lower than the maximum bearable temperature 85° C. of the chip. The heat dissipation requirements of future high power density devices and chip (GaN or SiC) power electronic devices are met, thereby avoiding thermal runaway damage.

1. A heat dissipation structure, comprising:
a heat dissipation channel; and
a plurality of heat dissipation fins arranged on at least one side of the heat dissipation channel, wherein heat dissipation fins arranged on a same side of the heat dissipation channel are arranged along an extension direction of the heat dissipation channel;
wherein the heat dissipation channel and the plurality of heat dissipation fins are each formed as a cavity structure; and each of the plurality of heat dissipation fins comprises a first end and a second end arranged opposite to each other, the first end is a closed end, the second end is an open end, and the second end communicates with the heat dissipation channel.

2. The heat dissipation structure according to claim 1, wherein
the heat dissipation channel extends along a first direction, the plurality of heat dissipation fins are arranged along the first direction, the plurality of heat dissipation fins extend along a second direction, and the first direction intersects the second direction; and
a distance between the first end of each heat dissipation fin and a horizontal plane is greater than or equal to a distance between the second end of the each heat dissipation fin and the horizontal plane.

3. The heat dissipation structure according to claim 2, wherein
the first direction is a horizontal direction, and the second direction is a vertical direction; or
the first direction is a vertical direction, and an included angle between the second direction and the first direction is less than or equal to 90°.

4. A heat dissipation system, comprising a heat dissipation structure of, wherein the heat dissipation structure comprises: a heat dissipation channel; and a plurality of heat dissipation fins arranged on at least one side of the heat dissipation channel, wherein heat dissipation fins arranged on a same side of the heat dissipation channel are arranged along an extension direction of the heat dissipation channel; wherein the heat dissipation channel and the plurality of heat dissipation fins are each formed as a cavity structure; and each of the plurality of heat dissipation fins comprises a first end and a second end arranged opposite to each other, the first end is a closed end, the second end is an open end, and the second end communicates with the heat dissipation channel;
a heat conduction cavity and a transmission channel, wherein the heat conduction cavity communicates with the heat dissipation structure through the transmission channel, and a connection end where the transmission channel is connected to the heat dissipation structure is higher than a connection end where the transmission channel is connected to the heat conduction cavity; and
a heat exchange medium, wherein the heat exchange medium in a liquid state is stored in the heat conduction cavity, the transmission channel is configured to transmit the heat exchange medium heated and vaporized in the heat conduction cavity to the heat dissipation structure and return the heat exchange medium condensed and liquefied due to a heat exchange at the heat dissipation structure into the heat conduction cavity.

5. The heat dissipation system according to claim 4, wherein the heat exchange medium comprises a heat superconducting phase change material.

6. The heat dissipation system according to claim 4, wherein the transmission channel is a rigid channel or a flexible channel.

7. The heat dissipation system according to claim 4, wherein the heat conduction cavity comprises a heat conduction base and a storage groove, wherein
the heat conduction base is disposed as a portion of a bottom surface of the heat conduction cavity;
the storage groove is disposed on the bottom surface of the heat conduction cavity and located on a side of the heat conduction base facing away from the heat dissipation structure; and
a surface of a side of the heat conduction base facing away from the heat conduction cavity is configured for a sample to be heat-dissipated to be attached to.

8. The heat dissipation system according to claim 7, wherein a thermal conductivity of the heat conduction base is greater than or equal to 500 W/(m·K).

9. The heat dissipation system according to claim 8, wherein a material of the heat conduction base comprises diamond.

10. The heat dissipation system according to claim 7, wherein
a ratio A00 of an area of the heat conduction base to an area of a heating surface of the sample to be heat-dissipated satisfies 5≤A00≤20000; and
a ratio A01 of a heat dissipation area of the heat dissipation structure to the area of the heat conduction base satisfies A01>B01, wherein B01 denotes a ratio of a heating power density of the sample to be heat-dissipated to a heat dissipation power density of natural gas convection.

11. The heat dissipation system according to claim 7, further comprising: a hydrophobic film layer, a hydrophilic film layer and a water-conducting film layer, wherein
the hydrophobic film layer covers at least one of an inner wall of the transmission channel, an inner wall of the heat dissipation channel or an inner wall of the plurality of heat dissipation fins;
the hydrophilic film layer covers at least a surface of the heat conduction base in the heat conduction cavity facing away from the sample to be heat-dissipated; and
the water-conducting film layer covers at least one of the following: a surface of the groove structure, or an inner surface of the heat conduction cavity between the heat conduction base and the groove structure.

12. The heat dissipation system according to claim 11, wherein the water-conducting film layer comprises a fiber structure or a core structure.

13. The heat dissipation system according to claim 7, wherein along a direction from the sample to be heat-dissipated to the heat conduction base, a thickness A11 of the heat conduction base satisfies 1 μm≤A11≤10 cm; and
along a direction from an inside of the heat dissipation structure to an outside of the heat dissipation structure, a thickness A12 between an inner wall of the heat dissipation structure and an outer wall of the heat dissipation structure satisfies 1 μm≤A12<10 cm.

14. A heat dissipation system, comprising the heat dissipation structure of claim 2, and further comprising:
a heat conduction cavity and a transmission channel, wherein the heat conduction cavity communicates with the heat dissipation structure through the transmission channel, and a connection end where the transmission channel is connected to the heat dissipation structure is higher than a connection end where the transmission channel is connected to the heat conduction cavity; and
a heat exchange medium, wherein the heat exchange medium in a liquid state is stored in the heat conduction cavity, the transmission channel is configured to transmit the heat exchange medium heated and vaporized in the heat conduction cavity to the heat dissipation structure and return the heat exchange medium condensed and liquefied due to a heat exchange at the heat dissipation structure into the heat conduction cavity.

15. A heat dissipation system, comprising the heat dissipation structure of claim 3, and further comprising:
a heat conduction cavity and a transmission channel, wherein the heat conduction cavity communicates with the heat dissipation structure through the transmission channel, and a connection end where the transmission channel is connected to the heat dissipation structure is higher than a connection end where the transmission channel is connected to the heat conduction cavity; and
a heat exchange medium, wherein the heat exchange medium in a liquid state is stored in the heat conduction cavity, the transmission channel is configured to transmit the heat exchange medium heated and vaporized in the heat conduction cavity to the heat dissipation structure and return the heat exchange medium condensed and liquefied due to a heat exchange at the heat dissipation structure into the heat conduction cavity.
